(19) United States
(12) Patent Application Publication
(10) Pub. No.: US 2019/0361058 A1
(43) Pub. Date: Nov. 28, 2019

(54) WORKLOAD OPTIMIZATION BASED ON ENERGY CHARACTERISTICS

(71) Applicant: dAlchemy Inc., Milpitas, CA (US)

(72) Inventors: K N Amarnath, Bengaluru (IN); C K Chandan, Tumkur (IN); Supriya Kulkarni, Bangalore (IN); Arvindh Raghavendran, Bengaluru (IN); Bharat Vijay, Milpitas, CA (US); Ram Bhoopalam, Milpitas, CA (US)

(21) Appl. No.: 16/423,194

(22) Filed: May 28, 2019

Related U.S. Application Data
(60) Provisional application No. 62/676,935, filed on May 26, 2018.

(51) Int. Cl. G01R 21/133; G05B 15/02

(52) U.S. Cl. CPC G01R 21/133; H04L 67/10; G05B 15/02

(57) ABSTRACT

Embodiments of the present invention disclose system for workload analyzing and optimization. The system includes one or more processors which are configured to capture, in real time, electrical signature data of one or more sub-systems running on a main system. The electrical signature is captured by one or more sensors coupled to a power controller. The captured electrical signature data into at least time domain or frequency domain. A volume of a workload of the one or more sub-systems is determined based on the converted data and a first threshold data. A type of the workload is determined based on the converted data and a second threshold data. A report is generated based on the determined volume and the type of workload.

This application claims the benefit of priority to U.S. Provisional Patent Application No. 62/676,935, which was filed on May 26, 2018, the entire specification of which is incorporated herein by reference.

### BACKGROUND

Large processing systems of today are designed for highly specialized solutions are designed to be dynamic in nature in order to adapt to changing business conditions. The main systems include smaller systems or sub-systems or distinct components. Each sub-system is operational to provide exclusive services which collectively provide a highly efficient, reliable and secure operational conditions and an optimal end solution for which they are designed for. The sub-systems or external systems integrated into the main system collectively provide services to the main system and are designed sophisticatedly and smartly in design. The sub-systems have the capability to dynamically adapt to the primary task that the overall system is performing. However, the sub-systems and supporting external systems do not always know the actual task or workload that they are performing or supporting. The type of workload bieng managed by each sub-system is a key consideration in tuning the main system. The current device monitoring systems rely on high amount of in-system instrumentation and logging to detect an ongoing or currently in effect workload condition. There are no solutions to dynamically classify the workload during usage, to-date. Also, there is no solution to study the electrical signature to know the type of workload on the device. Therefore, we require systems with capabilities to recognize, in real-time, the workload type being managed by each sub-system in order to broadcast it to all the sub-systems and to facilitate them to adapt dynamically. The system of the current invention will have the capability to auto-configure its sub-systems in order to achieve optimal performance of the overall workload and to provide an optimal desired outcome.

### SUMMARY

Embodiments of the present invention disclose workload analyzing apparatus which comprising a plurality of sensors to capture real time electrical signatures data of one or more sub-systems running on a main system. The one or more sensors may be coupled to a power controller of the main system The captured electrical signature data is converted into a time domain and into frequency domain using various algorithms and methods known in the art.

Workload volume of the sub-systems may be determined based on the time domain and frequency domain data.

Type of the workload is determined based on the time domain and frequency domain data.

A report may be generated and sent to the manufacturers or the user regarding the determined volume and the type of workload.

### BRIEF DESCRIPTION OF THE DRAWINGS

FIG. 1 is a schematic diagram illustrating an analysis and detection system.

FIG. 2 is a schematic illustrating the details of the analytics engine of FIG. 1.

FIG. 3 is a schematic illustrating application of the detection and analysis system in any target ecosystem.

FIG. 4 illustrates a schematic system used for mining data from any target ecosystem for analysis.

FIGS. 5A and 5B illustrates an example of the electrical power output over time.

FIG. 6 illustrates the data flow in case of detection of software with respect to FIG. 3 and FIG. 4.

FIG. 7 illustrates a model of data analytics for using the data from known data examples of software applications in accordance with an embodiment.

FIG. 8A illustrates frequency components of a signal.

FIG. 8B illustrates the process flow for using the frequency domain signals.

FIGS. 9A, 9B and 9C illustrates frequency domain heuristics of the resulting analysis to identify the software applications running on the storage server.

### DETAILED DESCRIPTION

In the following description, for purposes of explanation, numerous specific details are set forth in order to provide a thorough understanding of the invention.

Reference in this specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not others.

Moreover, although the following description contains many specifics for the purposes of illustration, anyone skilled in the art will appreciate that many variations and/or alterations to said details are within the scope of the present invention. Similarly, although many of the features of the present invention are described in terms of each other, or in conjunction with each other, one skilled in the art will appreciate that many of these features can be provided independently of other features. Accordingly, this description of the invention is set forth without any loss of generality to, and without imposing limitations upon, the invention.

As will be appreciated by one skilled in the art, the aspects of the present invention may be embodied as a system, method or computer program product. Accordingly, aspects of the present invention may take the form of an entirely hardware embodiment, an entirely software embodiment (including firmware, resident software, micro-code, etc.), or an embodiment combining software and hardware aspects that may all generally be referred to herein as a “circuit,” “module,” or “system.” Furthermore, aspects of the present invention may take the form of a computer program product embodied in one or more computer readable medium(s) having computer readable program code embodied thereon.

The workload of each sub-system of a main system collectively amount to the cumulative workload handled by the main system. Each sub-system is responsible to deliver a certain type of workload which may have unique power characteristics. When devices which fulfil multiple purposes are able to identify at run time the type of workload being handled, manufacturers have a better ability to tune the device functionality dynamically in real time. It is desirable to characterize the functioning of each of the sub-devices under different types of workload and gain insights into the overall performance. The ability to detect the workload at run time in a non-intrusive form gives device manufacturers invaluable insights and capabilities which includes dynamic configurability for best possible performance, detection of malware or potentially destructive execution sequences happening on the device.

Algorithms are primarily used to characterize the workload being serviced by each of the sub-devices based on the detected electrical parameters. The characterization of the power signature gives insights into multiple aspects of the workload, some of which are listed below:
1. Non-intrusive identification of the workload being handled by any of the devices, may be any of the following:
   a. The type and specific database application running on a computer or a storage sever.
   b. The software applications, running on a server. For examples user applications or application servers or web servers like tomcat using a particular server or storage device.
   c. The amount of load being put on mechanical devices such as the load in case of fans or simple motor driven devices.
   d. Characterizing the output part of UPS (Uninterrupted Power Supply) based on the load.
   e. Operating System, Version of the Operating System and the updates/fixes applied.
2. Health of the workload handled by any of the devices or problems in the output of any of the devices or machines are reflected in the electrical consumption characteristics of the devices.
   a. If the software using a particular server or storage is performing sub optimally due to bad tuning or lack of system update of the device, it will be indicated in the electrical characteristics. The power consumption parameters like power, current, voltage, reactive power and frequency are indicative of the output.
   b. Some mechanical devices like fans show the problems in their speed settings Vs output based on the power consumption parameters.
3. Device characterization
   a. If the software using a particular storage disk can be detected, then the disk manufacturers can automatically optimize disk performance via their storage controllers.
   b. Different server storage vendors do priming of SSDs (Solid State Drives). A power profile is useful to know the normal operation state and various states of operation.
4. Malware detection and intrusion detection on the devices.
   a. It is possible to baseline electrical parameters of a device and the patterns in various scenarios, using these patterns it is possible to classify an unexpected pattern as a malware or a harmful software which is not supposed to be running on a device. With proliferation of IoT devices malware running on any device is a drastic intrusion. Detection of a fundamental level of electrical parameters like power consumption makes detection of intrusion and malware simpler and stronger.

Sampling the electrical characteristics of sub-systems and measuring them at suitable rate brings in a different dimension to the approach to solve the problem of workload characterization. It may be advantageously and non-intrusively be built into the power source to a device or-subsystem of the device. With the technology of power/electrical signatures this may be applied to even devices which do not have inherent capability to collect data. This means existing hardware can become intelligent and give users insights about the workload when attached to any system externally. This is highly applicable in case of simple devices like cooling fans, UPS (Uninterrupted Power Supply) units which are critical equipment but do not have much data acquisition and self-diagnostics capability.

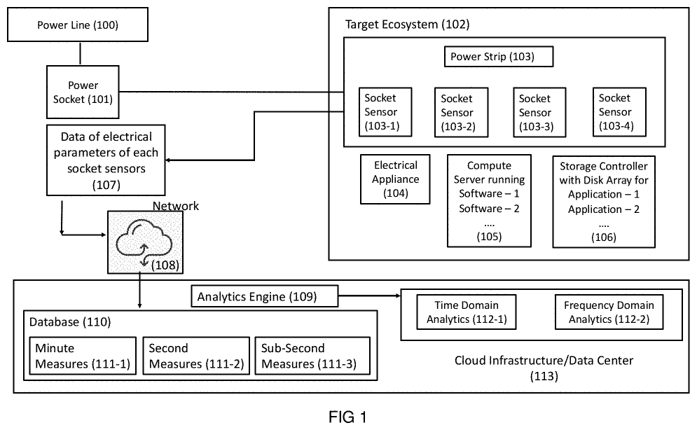

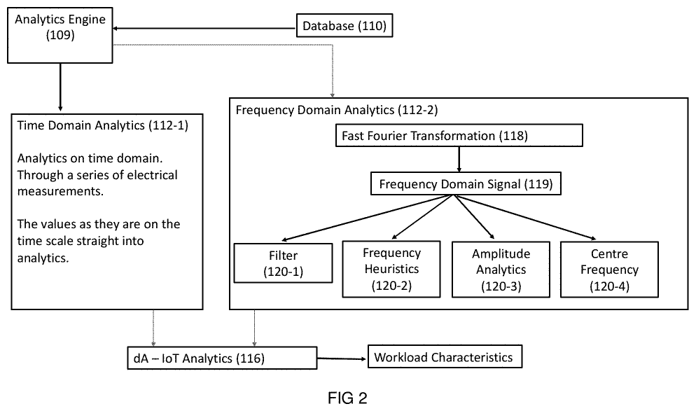

Referring to FIG. 1, a schematic diagram of an analysis and detection system in accordance with one embodiment is shown. The system utilizes a unique way of determining workload characteristics of any electrical device using the power consumption characteristics of the electrical devices and sub-systems. The electrical devices may range from simple electrical devices to computers, servers running software applications or storage controllers which handle storage for the software application which may run in a data center. The workload here refers to the load on the devices in case of simple devices like of a fan is the speed of the rotation of its blades, in case of computing servers and storage is the application using the hardware. The electrical devices (104), (105) or (106) are required to be connected to power terminals each of which includes socket sensors (103-1, 103-2, 103-3 or 103-4). The socket sensors (103-1 to 103-4) are part of a sensor power strip (103) and are configured to measure electrical parameters of each electronic devices at various sampling rate. The data collected from the corresponding socket sensors are individually collected at (107) for each electrical device. The collected data is then sent into a cloud infrastructure or a central server (108). The Analytics Engine (109) works intelligently on the collected data received from the central server (108) in order to determine the workload type and workload amount for each electrical device (104-106). The analytics engine (109) works on a cloud infrastructure or a data center (113), the data collected from any of the socket sensors in (107) is transmitted through the cloud network (108) to a database (110) of the analytics engine (109). The databases (110) contains data corresponding to the measurements made at different durations such as minutes, seconds or sub-seconds. These measurements are voltage, current, power factor/reactive power, average power and frequency/phase shift and so on. The working of the analytics engine (109) is described in detail with reference to FIG. 2.

Referring to FIG. 2, an analytics engine (109) is illustrated in accordance with an embodiment. The analytics engine (109) analyses the data in database (110), of FIG. 1, by generating two visualizations of the data. The data can be analyzed in time domain (112-1) which may be detected at different time periods. The data may be transformed into frequency domain (112-2) based on the frequency characteristics of the data. The frequency characteristics are indicative of the workload characteristics. The dA_IoT Analytics block (116) may use either of the two representations or a combination of both to be able to provide insights into the workload.

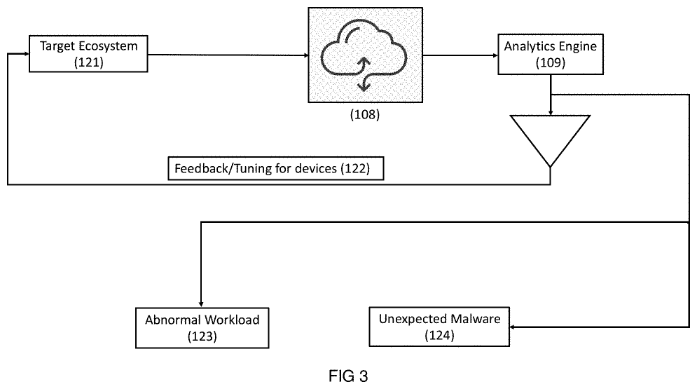

With reference to the FIG. 3, a schematic is illustrated application of the detection and analysis system in any target ecosystem. In an embodiment, the target ecosystem 121 refers to an exemplary system in which electrical devices are connected by means of socket sensors 103-1, 103-2, 103-3 and 103-4 of FIG. 1. Further, the electrical parameters detected by the socket sensors is transmitted through the network 108 to the database 110 as shown in FIG. 1. The data related to the electrical parameters is collected and stored in the database 110 which is further processed by the analytics engine 109. In an embodiment, the characteristics of the workload determined is used as a feedback 122 for tuning or optimizing of the target ecosystem 121. As the analytics engine 109 is trained to determine the difference between expected electrical profile and abnormal workload 123 or unexpected malware 124 based on the detected electrical parameters. The detection of unexpected workload (123) applies to the volume of the valid workload.

The performance of various devices is different in their target ecosystem. The behavior of an electrical device has a specific signature of power consumption. Analytics algorithms are used to determine types of workload and volume of workload of devices based on electrical parameters. Anomalies in the values of electrical parameters are also detected by using the algorithms. This is possible because workload and the volume of the workload each have specific electric signatures. In an embodiment power consumption signatures are used as a significant data point to understand machine workload performance, health, activity on the machine and type. The data related to voltage, current, frequency and reactive power is indicative of how the machine is consuming power and further relates to its output. Any device or a sub-system of a device which consumes electricity has a specific pattern of consumption. This may be termed as the electricity or power signature of the device or sub-system. This signature is indicative of different aspects of the workload.

The power signature is a combination of various values of the electrical parameters and their values over a time period. The sampling done on the values of these electrical parameters and measurement can be as low as 1 second or less. The data stored in a server or a cloud-based server is then available for analysis. The data analytics and machine learning algorithms will then be applied to the aggregated data to determine patterns. With signals on a time scale it is possible to apply FFT (Fast Fourier Transforms) to decipher the frequency domain signature. This becomes very indicative of multiple insights on the system workload.

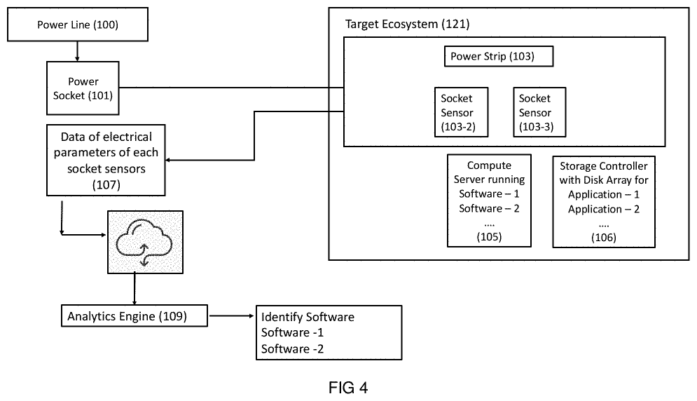

Referring to FIG. 4, a schematic system for mining data from any target ecosystem for analysis by from a target ecosystem 121. In an embodiment, there may be different applications running on a server (105) of the target ecosystem 121. The socket sensor (103-2) connected to the target ecosystem 121 senses electrical parameters, which is collected as data in 107. The data is analyzed by the Analytics Engine 109 to identify the software being run on the server 105. In case of data center which in this case could be the target ecosystem (121) the server manufacturers do not have run time knowledge of the applications being run on the servers over different periods of time. The same applies to Storage controllers (106) where manufacturers do not know about the applications which are using a disk. In this case the socket sensor (103-3) measures the electrical parameters, which are stored in the database and analyzed by the analytics engine (109).

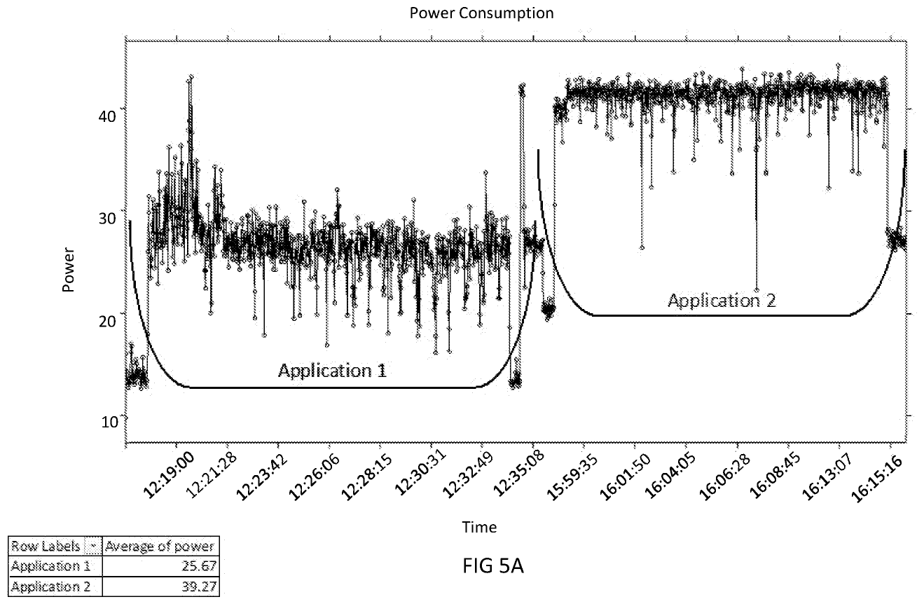

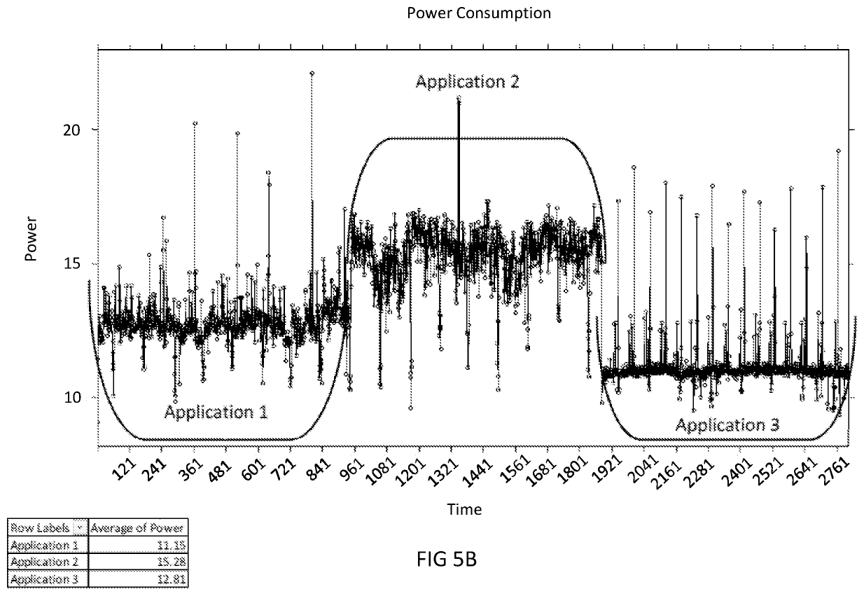

Referring to FIG. 5A, an example of the electrical power output over time is shown, when “Application 1” and “Application 2” are running on a server. FIG. 5B shows two applications with different operations having distinct power values over time. The following figure shows how this changes with a third “UNKNOWN” application is introduced.

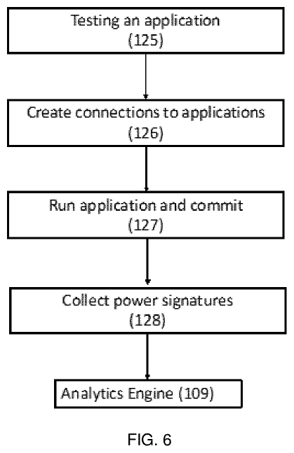

Referring to FIG. 6, the flow of data is illustrated in case of detection of software with respect to embodiments of FIG. 3 and FIG. 4. The process begins with beginning to test an application in step 125. The sensor connections are created with the target ecosystem running the applications in step 126. The target ecosystem collects the power signatures based on the running of the application in step 127 via the sensors. The data collected from the target ecosystem with respect to the running applications is sent to the analytics engine 109 for analysis.

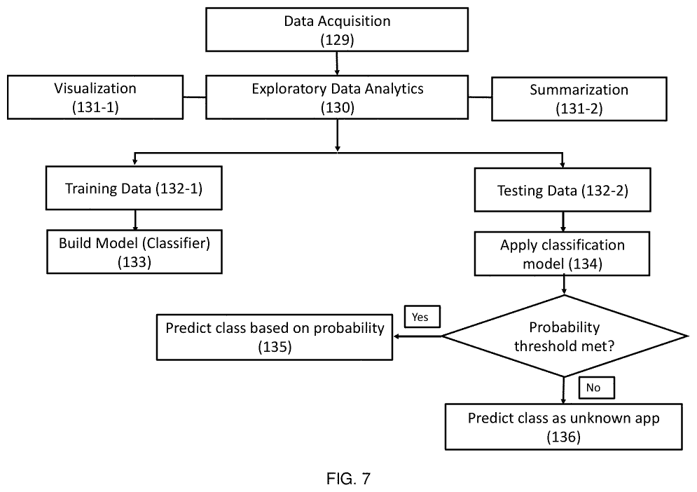

Referring to FIG. 7, a model of data analytics for using the data from known data examples of software applications in accordance with an illustrative embodiment. The data is acquired from devices running the software applications in the step 129. The acquired data is processed in time domain and in frequency domain in the visualization block 131-1. The data is processed in either the time domain or the frequency domain and is used to gain insights related to the workload of the software applications and to recognize or classify the software applications. Various algorithms known in the art may be used in the visualization block 131-1 such as numpy, pandas, math sklearn, decisionTree, Logistic, Naïve Bayes, KNN, ID3, SVM, Random Forest, GBM, xgboost and so on.

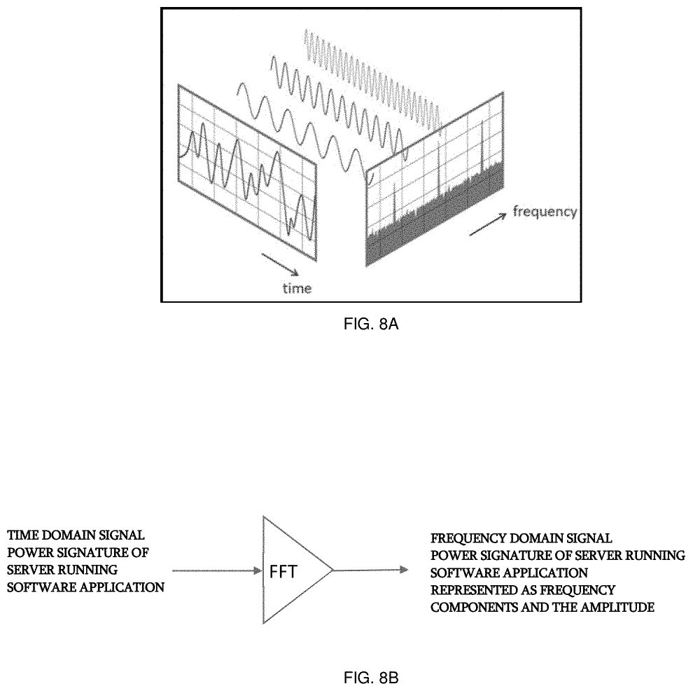

A fast Fourier transform (FFT) may be used as an algorithm for sampling a signal over a period of time (or space). FFT further divides the signal into its frequency components. These components are single sinusoidal oscillations at distinct frequencies each with their own amplitude and phase. This transformation is illustrated in the FIG. 8A. Over the time period measured in the FIG. 8A, the signal as shown in the Figure contains 3 distinct dominant frequencies.

An FFT algorithm computes the discrete Fourier transform (DFT) of a sequence, or its inverse (IFFT). Fourier analysis converts a signal from its original domain to a representation in the frequency domain and vice versa. An FFT rapidly computes such transformations by factorizing the DFT matrix into a product of sparse (mostly zero) factors. As a result, it manages to reduce the complexity of computing the DFT from O(n²), which arises if one simply applies the definition of DFT, to O(n log n), where n is the data size.

The power consumption profiles are time domain signals which are unique for each of the databases. These power consumption signals are in form of a waveform, this waveform can be transformed to be viewed in the frequency domain. There are multiple ways to view this signal and work with it in the frequency domain. The process flow for using the frequency domain signals is as shown in FIG. 8B.

Each of the software applications have their own specific power signatures. This results in a specific frequency domain distribution after going through the FFT as shown in FIG. 8B.

In the exploratory data analytics block 130 the acquired data may be processed to either generate training data in 132-1 or may be used as testing data in 132-2.

The Training data in 132-1 is used to build model (classifier) in block 133. Various algorithms may be used to detect different power signatures which are then used as data to build classification models. The classification models built are then used to identify similar patterns of power signatures for classifying and identifying different devices or applications. In an embodiment, the classification model data may be pre-fed into the build model block 133 during configuration.

In the testing data block 132-2 the acquired data 129 may be classified in the apply classification model block 134 based on the classification model data of build model block 133. The acquired data is compared with the classification model data in order to check if the comparison result is above or below the probability threshold. In case, the comparison meets the probability threshold then the data with respect to the application is classified based on the know model data. In case, the comparison result does not meet the probability threshold then the application is classified as an unknown application.

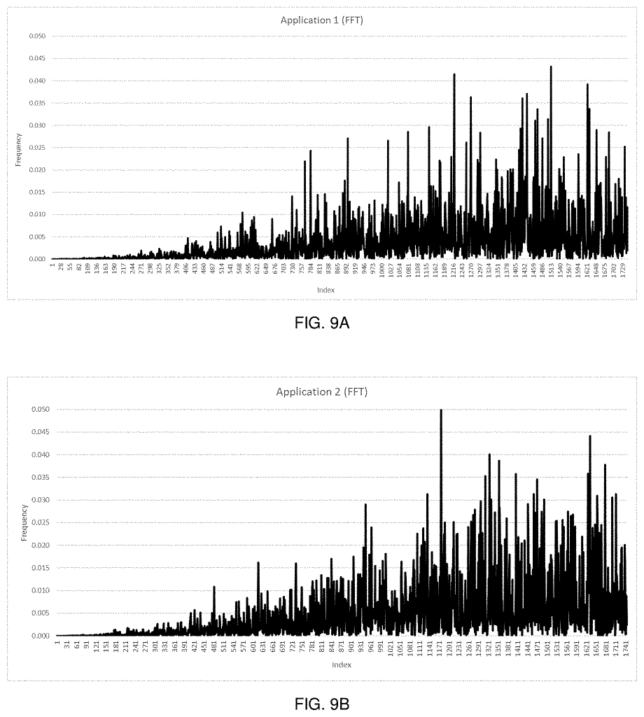

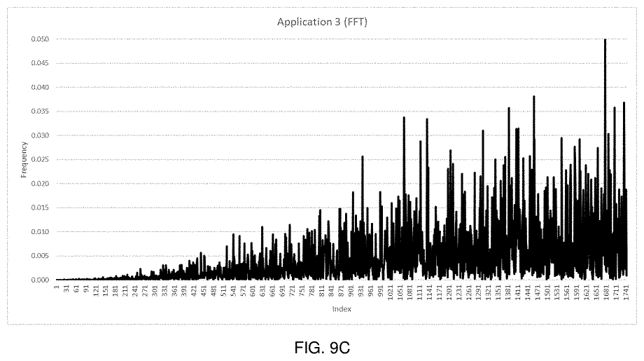

When multiple software applications are running simultaneously they may be disambiguated using FFT. The resulting power signature on the time domain is transformed to the frequency domain in the visualization block 131-1. The resulting signal is an addition of various frequency components of the different applications. With the concepts of the Centre Frequency and Frequency domain heuristics the resulting analysis may be used to identify the software applications running on the storage server as shown in FIGS. 9A, 9B and 9C. Thus, software may be accurately classified based on the following methods: (1) Each frequency domain signal has a center frequency and harmonics with various amplitudes. These are found to be unique for every different software running. (2) Each software running on the system generates a frequency domain signal after going through the FFT, the heuristics like average power across different frequencies and power distribution across frequencies may be used to identify a particular software.

A set of algorithms when tuned to detect different power signatures are then said to have been trained with the data. They are then ready to identify similar patterns across different devices. These set of algorithms which are trained and tuned are referred to as the Analytics Engine 109. When devices having workload generate power signatures the Analytics Engine 109 is able to identify the workload and its various characteristics. This in-turn provides the functionality described in the previous sections. Some examples of the functionality is as below:
1. The different power signatures sensed can be used to understand the different software that are accessing the storage element.
2. The analytics algorithms are capable of classifying the software accessing the disk.
3. This can be done even if the storage devices are running a virtual machine running multiple software at the same time.
4. In this case described below the algorithms are able to classify the various software which are accessing the disk.

Although the invention is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

1. A workload analyzing apparatus comprising:
one or more processors configured to:
capture, in real time, electrical signature data of one or more sub-systems running on a main system, wherein the electrical signature is captured by one or more sensors coupled to a power controller;
convert the captured electrical signature data into at least one of a time domain data or a frequency domain data;
determine a volume of a workload of the one or more sub-systems based on the converted data and a first threshold data;
determine a type of the workload based on the converted data and a second threshold data;
generate a report based on the determined volume and the type of workload.
